(19) United States
(12) Patent Application Publication
(10) Pub. No.: US 2024/0170594 A1
(43) Pub. Date: May 23, 2024

(54) SOLAR CELL STRING AND METHOD FOR PRODUCING A SOLAR CELL STRING

(71) Applicant: FRAUNHOFER-GESELLSCHAFT ZUR FÖRDERUNG DER ANGEWANDTEN FORSCHUNG E. V., Munchen (DE)

(72) Inventors: Jan NEKARDA, Freiburg (DE); Jan PASCHEN, Freiburg (DE); Oliver JOHN, Freiburg (DE); Gernot EMANUEL, Freiburg (DE)

(73) Assignee: FRAUNHOFER-GESELLSCHAFT ZUR FÖRDERUNG DER ANGEWANDTEN FORSCHUNG E. V., Munchen (DE)

(21) Appl. No.: 18/282,660

(22) PCT Filed: Mar. 17, 2022
(86) PCT No.: PCT/EP2022/056944

§ 371 Date: Sep. 18, 2023

(30) Foreign Application Priority Data
Mar. 18, 2021 (DE) 10 2021 106 598.4

(51) Int. Cl. H01L 31/05

(52) U.S. Cl. CPC H01L 31/0508

(57) ABSTRACT

A solar cell string, includes a first photovoltaic solar cell A and at least one second photovoltaic solar cell B, the solar cell A having at least one metallic electrode A and the solar cell B having at least one metallic electrode B, the electrode A being electrically conductively connected to the electrode B by a cell connector of the solar cell string. The cell connector is a flexurally slack cell connector, at least partly covering a side of the solar cell A and the electrode A in a cell connector covering region A, the connector is at least partly directly electrically conductively connected to the electrode A in the connector covering region A. The cell connector is at least partly directly electrically conductively connected to the electrode B in the cell connector covering region B, and the cell connector covering region A or the cell connector covering region B.

### FIELD OF THE INVENTION

The invention relates to a solar cell string and to a method for producing a solar cell string.

### BACKGROUND

The use of photovoltaic solar cells for converting electromagnetic radiation into electrical energy typically takes place with a solar cell module having a plurality of solar cells.

Such solar cell modules typically have a plurality of solar cell strings. A solar cell string comprises a plurality of solar cells which are electrically conductively connected to one another. Solar cells in a solar cell string are typically connected in series since a single solar cell generates a rather low voltage, but a high current.

Typical solar cells have two metallic contacting structures, so-called electrodes. A p-electrode is electrically conductively connected to a p-doped region of the solar cell, and an n-electrode is electrically conductively connected to an n-doped region of the solar cell.

The series interconnection of solar cells in a solar cell string is typically made by means of a rigid cell connector which electrically conductively connects the metallic contacting structure of one solar cell to a metallic contacting structure of an adjacent solar cell. The electrically conductive connection is typically made in order to form a series circuit, such that the n-electrode of one solar cell is electrically conductively connected to the p-electrode of the adjacent solar cell, or vice versa.

However, such a cell connector has disadvantages in respect of handling during the production of the solar cell string. In addition, mechanical stresses as a result of a mechanical load of the solar cell string, in particular owing to a thermal load, may lead to an increase in the contact resistance between cell connector and solar cell through to a contact interruption upon detachment of the cell connector. Furthermore, these rigid cell connectors exert thermomechanical stress on the cells that can lead to cell fracture. There is therefore a need for a cost-effectively producible and nevertheless robust solar cell string and also a method for producing same. Moreover, typical cell connectors require a minimum distance between the adjacent solar cells owing to the thickness of the cell connectors and the limitation of the bending radii. There is a need to reduce this minimum distance.

### SUMMARY

Therefore, the present invention is based on the object of providing such a solar cell string and a method for producing such a solar cell string.

This object is achieved by means of a solar cell string, and also a method for producing a solar cell string as set forth in the appended claims. Advantageous configurations are also found in the appended claims.

The solar cell string according to the invention is preferably produced by means of the method according to the invention, in particular a preferred embodiment thereof. The method according to the invention is preferably configured for producing a solar cell string according to the invention, in particular an advantageous embodiment thereof.

The solar cell string according to the invention comprises a first photovoltaic solar cell A and at least one second photovoltaic solar cell B, the solar cell A having at least one metallic electrode A and the solar cell B having at least one metallic electrode B, and the electrode A being electrically conductively connected to the electrode B by means of a cell connector of the solar cell string.

What is essential is that the cell connector is a flexurally slack cell connector,
that the cell connector at least partly covers a side of the solar cell A and the electrode A in a cell connector covering region A, and the cell connector is at least partly directly electrically conductively connected to the electrode A in the cell connector covering region A,
that the cell connector at least partly covers a side of the solar cell B and the electrode B in a cell connector covering region B, and the cell connector is at least partly directly electrically conductively connected to the electrode B in the cell connector covering region B, and
that the cell connector covering region A and/or the cell connector covering region B, preferably the cell connector covering region A and the cell connector covering region B, have/has a width of less than 1000 μm, in particular less than 500 μm, preferably less than 300 μm.

The solar cell string according to the invention has the advantage that firstly the solar cells A and B are connected by means of a flexible cell connector. The latter can at least partly compensate for mechanical loads, without a mechanical load arising at the contact areas between cell connector and solar cell. The flexible connection furthermore has the advantage that the cells can be positioned both next to one another and with a small overlap one above another. The method is thus suitable for a variety of module concepts. Flexible cell connectors also enable larger bending radii compared with rigid cell connectors, and so adjacent solar cells can be arranged at a smaller distance from one another when the solar cells are arranged next to one another.

Moreover, cost-effective flexible cell connectors are available; more particularly preferably, the cell connector used is a metal foil, preferably an aluminum foil. Furthermore, handling in the production method is simplified since there is no need to handle a rigid solar cell string typically comprising a multiplicity of solar cells. According to the applicant's investigations, the small width of the cell connector covering region A and/or B is sufficient for forming electrical contacting with high quality, i.e. with a low contact resistance. At the same time, the small width results in little shading vis-à-vis incident electromagnetic radiation at the front side.

The invention is therefore furthermore based on the insight that, owing to the good conductivity of the cell connector, there is no need for the cell connector to cover a large area of a back side or front side of the solar cell A or B. The good conductivity also makes possible a small contact area between cell connector and electrode, for which reason the electrodes on the cell can be formed in a manner that saves a great deal of material. The soldering regions for cell connectors that are required in the case of previously known types of connections can be significantly reduced in size.

The solar cell string according to the invention comprises at least two solar cells. However, it is advantageous for the solar cell string to comprise further solar cells, in particular at least four, preferably at least eight, in particular at least ten, solar cells, in which case each solar cell comprises at least two electrodes, the solar cells are arranged in a series, and adjacent solar cells are electrically conductively connected to a cell connector, as described, by virtue of the cell connector electrically conductively connecting an electrode of one solar cell to an electrode of the adjacent solar cell, preferably in a series circuit.

The abovementioned width of the cell connector covering region A extends perpendicular to that edge of the solar cell A which faces the solar cell B. Accordingly, the length of the cell connector covering region A extends parallel to this solar cell edge.

Likewise, the width of the cell connector covering region B extends perpendicular to that edge of the solar cell B which faces the solar cell A. Accordingly, the length of the cell connector covering region B extends parallel to this solar cell edge.

In order to achieve a low conduction resistance of the cell connector, it is advantageous for the cell connector covering region A to have a length which is greater than 80%, preferably greater than 90%, more particularly preferably greater than 95%, of the side length of the solar cell A at the cell connector covering region A.

Furthermore, and more particularly preferably in addition, it is advantageous that the cell connector covering region B has a length which is greater than 80%, preferably greater than 90%, more particularly preferably greater than 95%, of the side length of the solar cell B at the cell connector covering region B.

The applicant's investigations have shown that a sufficiently low conduction resistance between electrode and cell connector can be achieved even if the electrode does not completely cover the solar cell in the region in which the solar cell is covered by the cell connector. As a result, material of the electrode can be saved and, depending on the structure of the solar cell, advantages are also afforded since there are typically high charge carrier recombination rates at interfaces between semiconductor and metal.

It is therefore advantageous that the electrode A does not completely cover the cell connector covering region A, and that in at least one region not covered by the electrode A, preferably in a plurality of such regions, the cell connector is mechanically and electrically non-conductively connected to the solar cell A.

Furthermore, and more particularly in addition, it is advantageous that the electrode B does not completely cover the cell connector covering region B, and in that in at least one region not covered by the electrode B, preferably in a plurality of such regions, the cell connector is mechanically and electrically non-conductively connected to the solar cell B.

One such region or preferably a plurality of such regions thus serve(s) to increase the mechanical stability without disadvantages in respect of the electronic quality of the solar cell or electrical loss owing to conduction resistances when the solar cells are connected.

Typical metallic electrodes are configured in the manner of a comb or double comb pattern and have so-called busbars with metallic fingers extending therefrom in a manner projecting perpendicularly. The fingers have a smaller cross-sectional area than the busbar since the charge carriers collected by the fingers are transported to the busbar and a larger cross-sectional area is therefore advantageous at the busbar in order to avoid cell resistance losses.

In the case of the solar cell string according to the invention, however, in one advantageous configuration, a busbar can be dispensed with at least in one or advantageously in both cell connector covering regions.

It is therefore advantageous that the electrode B has a plurality of metallic fingers, preferably rectilinear fingers that run parallel, the fingers not being directly connected by metallic elements of the electrode B in the cell connector covering region B, and the cell connector being directly electrically conductively connected to at least 50%, preferably to at least 80%, more preferably to all, of the fingers of the electrode B,

Furthermore, and more particularly in addition, it is advantageous that the electrode A has a plurality of metallic fingers, preferably rectilinear fingers that run parallel, the fingers not being directly connected by metallic elements of the electrode A in the cell connector covering region A, and the cell connector (4, 4′) being directly electrically conductively connected to at least 50%, preferably to at least 80%, more preferably to all, of the fingers of the electrode A.

During the production of fingers of an electrode, finger regions having a thin cross-section and thus a high conduction resistance or else interruptions of the fingers may arise owing to manufacturing tolerances. It is therefore advantageous that outside the cell connector covering region, in particular at the edge side situated opposite the cell connector covering region, at least two fingers are electrically conductively connected to one another by a metallic cross-connector.

Such a cross-connector need not have the customary cross-sectional area of a busbar, rather the cross-connector advantageously has the cross-sectional area of the fingers. This is because the cross-connector does not have to fulfil the function of passing on all the charge carriers collected by the fingers, but rather only the function, in the event of a manufacturing fault having caused a finger to be interrupted, of distributing the charge carriers collected by this segment of the finger to the other fingers. In one advantageous embodiment, at least two fingers of the electrode are electrically conductively connected by the cross-connector, in particular in each case at least two fingers are electrically conductively connected to one another by means of a plurality of cross-connectors, preferably in such a way that each finger is electrically conductively connected at least to a further finger by means of a cross-connector. The cross-connectors are preferably arranged at the edge side situated opposite the cell connector covering region.

In one advantageous configuration, all the fingers of the electrode are electrically conductively connected by means of a common cross-connector.

It is therefore advantageous that outside the cell connector covering region B, in particular at the edge side situated opposite the cell connector covering region B, the fingers are electrically conductively connected to one another by a metallic cross-connector of the electrode B.

Furthermore, and more particularly in addition, it is advantageous that outside the cell connector covering region A, in particular at the edge side situated opposite the cell connector covering region A, the fingers are electrically conductively connected to one another by a metallic cross-connector of the electrode A.

The present invention makes possible the configuration—known per se—of the cell connector which is connected to the back side of the solar cell A in a Z-structure, is led between solar cell A and solar cell B to the front side of the solar cell B and is connected to the solar cell B at the front side thereof. In this advantageous configuration, the electrode A is thus arranged at the back side of the solar cell A, and the electrode B is arranged at the front side of the solar cell B.

However, the use of the flexible cell connector makes possible further advantageous configurations which make possible in particular novel, cost-effective production methods:

In a further advantageous configuration, the solar cells of the solar cell string are configured as back-side contactable solar cells. In the case of such solar cells, both the n-doped region and the p-doped region can be contacted from the back side. Multiple back-side contactable solar cell structures are known, in particular solar cells which do not have a metallic electrode on the front side. Likewise, solar cells are known which have a metallic electrode on the front side, in which case the front-side metallic electrode is led to a metallic contacting area at the back side by means of a metallic connection. Such structures are known as MWT structures, for example.

In the advantageous configuration in which solar cell A and solar cell B are configured as back-side contactable solar cells, therefore, electrode A is arranged at the back side of the solar cell A and also electrode B is arranged at the back side of the solar cell B. Electrodes A and B of the solar cells arranged next to one another are connected at the back side by the cell connector.

Typical solar cells are thin, large-area structures having a front side and a back side, these having a large area, and edge sides having a considerably smaller area than front and back sides.

Advantageously, the cell connector is electrically conductively connected to the electrode A and to the electrode B at the front side or at the back side of the respective solar cell. This affords the advantage that a large area or a long length in the case of the configuration of the electrodes with metallization fingers is available for forming the electrically conductive connection, and there is thus a fault tolerance with regard to a spatial displacement.

In one advantageous configuration, however, the present invention makes possible a further form of the formation of the electrically conductive connection between cell connector and electrode, the cell connector being electrically conductively connected to the electrode at an edge side of the electrode. In this phenomenal embodiment, in contrast to customary practice, the electrically conductive connection is therefore not made exclusively, preferably not made, at the front side or at the back side of the solar cell, but rather at an edge side.

It is therefore advantageous that the cell connector covering region A is arranged at an edge side of the electrode A, and or, preferably and, that the cell connector covering region B is arranged at an edge side of the electrode B.

As described above, the edge sides of the solar cells are those sides having a small area which are not the front or back side of the solar cell. In the case of the advantageous embodiment mentioned above, the cell connector is thus arranged at least at an edge side of the metallization of the solar cell which is not the front or back side of the solar cell. In particular, it is advantageous that the connection is effected exclusively at edge sides, such that there is no connection between cell connector and solar cell at a front or back side and, consequently, the cell connector covering region A is not arranged at the back side or front side of the solar cell A and/or, preferably and, the cell connector covering region B is not arranged at the front side or back side of the solar cell B.

In order to increase the mechanical stability, it is advantageous that the cell connector is arranged mechanically and electrically non-conductively at an edge side of the solar cell A and/or, preferably and, at an edge side of the solar cell B. Such an arrangement can preferably be carried out in an edge region of the solar cell which is formed by the substrate, typically a semiconductor substrate, in particular typically a silicon substrate.

With the use of solar cells which each have an electrode at the front side and an electrode at the back side, it is advantageous to form the electrodes at a respective edge of the solar cell in a manner spaced apart from the solar cell edge, in particular as described below:

In this advantageous embodiment, therefore, solar cell A has an electrode at the front side and an electrode at the back side, and solar cell B likewise has an electrode at the front side and an electrode at the back side. Electrode A is for example the back-side electrode of the solar cell A and electrode B is for example the front-side electrode of the solar cell B. It is likewise within the scope of the invention for electrode A to be the front-side electrode of the solar cell A and electrode B to be the back-side electrode of the solar cell B.

The electrodes of the solar cells A and B are preferably configured in such a way that, at a respective edge, the front-side electrode of the solar cell terminates flush with the edge. The converse arrangement is formed at the opposite edge: there the back-side electrode preferably terminates flush with the edge of the solar cell. It is thereby possible, in a simple manner, to form an electrically conductive connection at the edge of the solar cell A and at the edge of the solar cell B between electrodes and cell connector.

Preferably, the back-side electrodes of the solar cells A and B are configured in such a way that the back-side electrode of the solar cell A and B is in each case arranged in a manner spaced apart at the edge, preferably with a distance of at least 100 μm, more preferably at least 200 μm, in particular at least 500 μm, at which the front-side electrode terminates flush with the edge. Likewise, the front-side electrodes of the solar cells A and B are preferably configured in such a way that the front-side electrode of the solar cells A and B is in each case spaced apart from the edge, preferably with a distance of at least 100 μm, more preferably at least 200 μm, in particular at least 500 μm, at which the back-side electrode terminates flush with the edge.

This spacing apart avoids a short circuit between the cell connector and the electrode spaced apart from the edge.

It is thus advantageous to form the electrodes of the solar cell A and the solar cell B in such a way that, at a respective edge, the front-side electrode of the solar cell terminates flush with the edge, whereas the back-side electrode of the solar cell is spaced apart at this edge, preferably with a distance of at least 100 μm, more preferably at least 200 μm, in particular at least 500 μm. The converse arrangement is preferably formed at the opposite edge of the solar cell A and the solar cell B: there the back-side electrode preferably terminates flush with the edge of the solar cell, whereas the front-side electrode is preferably spaced apart from the edge, preferably with a distance of at least 100 μm, more preferably at least 200 μm, in particular at least 500 μm.

In order to optimally utilize a predefined area, solar cell strings are known in which the solar cells are arranged using shingle technology. In this case, two adjacent solar cells overlap, such that a back-side overlap region at the back side of one solar cell is arranged over a front-side overlap region of the front side of the adjacent solar cell and between these overlap regions there is the electrically conductive connection for forming a string.

It is known for the solar cells of such a solar cell string to be connected to one another in the overlap region by means of conductive adhesive so that a rigid solar cell string arises.

A further advantageous configuration is based on the insight that conventional solar cell structures having rigid metallic electrodes at the front and back sides can be used for producing a cost-effective solar cell string using shingle technology if a flexible cell connector is used which, at least on the front side, only slightly covers the front side of the solar cell to be contacted.

In this advantageous configuration, the solar cells are arranged in an overlapping fashion, such that the solar cells A and B are arranged in an overlapping fashion, such that a back-side overlap region of the back side of the solar cell A is arranged over a front-side overlap region of the front side of the solar cell B,
such that the electrode A is arranged at the back side of the solar cell A and is configured to conduct electrical charge carriers at the back side of the solar cell A to the back-side overlap region or to conduct them away from the latter,
such that the electrode B is arranged at the front side of the solar cell B and is configured to conduct electrical charge carriers at the front side of the solar cell B to the front-side overlap region or to conduct them away from the latter,
such that the cell connector is arranged electrically conductively at the electrode A in the back-side overlap region and electrically conductively at the electrode B in the front-side overlap region.

A flexible solar cell string in a shingle arrangement is realized as a result.

Advantageously, the back-side overlap region and the cell connector covering region A are identical, and or, preferably and, the front-side overlap region and the cell connector covering region B are identical, such that material is saved by comparison with variants with multiple folding of the cell connector.

Advantageously, the solar cells of the solar cell string are configured as bifacial solar cells. This affords the advantage that not only electromagnetic radiation incident from the front side but also electromagnetic radiation incident from the back side can be converted into electrical energy.

The solar cell string according to the invention is suitable in particular for configuration for bifacial use since, as described above, busbars can be dispensed with, such that on the back side as well, by virtue of an advantageous configuration of the back-side electrode with fingers and preferably a cross-connector, there is only little covering of the back side by the metallic electrode, and so there is little shading vis-à-vis electromagnetic radiation impinging from the back side.

The cell connector is preferably configured as a foil. It lies within the scope of the invention to use nonmetallic, conductive foils.

The configuration of the cell connector as a metallic foil, preferably as a metal foil, more particularly preferably as an aluminum foil, is particularly simple in terms of handling and advantageous owing to low conduction resistances.

The configuration of the cell connector as a copper foil or silver foil likewise lies within the scope of the invention.

In one advantageous configuration, the cell connector is configured as a metal foil composed of the metal which is an essential metallic constituent of the electrode contacted by means of the cell connector.

If the electrode comprises silver as an essential metallic constituent, for example, then the cell connector is correspondingly preferably configured as a silver foil. If copper is an essential metallic constituent of the electrode, the cell connector is preferably configured as a copper foil.

It lies within the scope of the invention to use a coated flexible foil or an uncoated flexible foil as cell connector. The use of a multilayer or monolayer flexible foil likewise lies within the scope of the invention.

For cost saving purposes, the cell connector is preferably configured as a monolayer, more particularly preferably uncoated, foil in order to reduce the costs.

The thickness of the cell connector is preferably in the range of 5 μm to 50 μm.

The object mentioned in the introduction is furthermore achieved by means of a solar cell module comprising a plurality of solar cell strings, wherein the solar cell strings are each configured as a solar cell string according to the invention, in particular as a preferred embodiment thereof.

The solar cell strings are electrically conductively connected to one another in a manner known per se.

Furthermore, the object formulated in the introduction is achieved by means of a method for producing a solar cell string. The method comprises the following method steps:
A. providing a first photovoltaic solar cell A and at least one second photovoltaic solar cell B,
   provision being made of the solar cell A comprising at least one metallic electrode A and the solar cell B comprising at least one metallic electrode B;
B. forming an electrically conductive connection between the electrode A and the electrode B by means of a cell connector.

What is essential is that the cell connector is arranged in a manner covering the electrode A in a cell connector covering region A, and the cell connector is at least partly directly electrically conductively connected to the electrode A in the cell connector covering region A,
that the cell connector is arranged in a manner covering the electrode B in a cell connector covering region B, and the cell connector is at least partly directly electrically conductively connected to the electrode B in the cell connector covering region B,
the cell connector being arranged at the electrode B in such a way that the cell connector covering region B in which the cell connector covers a front side of the solar cell B has a width of less than 1000 μm, in particular less than 500 μm, preferably less than 300 μm,
the connection between the cell connector and at least the electrode B, preferably between the cell connector and the electrode A and the electrode B, being made by way of the action of heat by means of laser radiation.

The small width of the covering region affords the advantages already described above in regard to the cell connector back-side covering region, in particular a material saving.

The method according to the invention has the advantages of the solar cell string according to the invention. Moreover, a particularly cost-effective method is attained by the use of laser radiation for forming the electrically conductive connection between the cell connector and at least the electrode B, preferably between cell connector and electrode A and electrode B.

Advantageously, the cell connector is at least partly melted by means of the laser radiation in order to form the connection.

Advantageously, the cell connector covering region A is arranged at an edge side of the electrode A, and or, preferably and,
a. the cell connector covering region B is arranged at an edge side of the electrode B. This affords the advantages mentioned above; in particular, during production, in one advantageous development, the solar cells can be arranged parallel to one another and processed from one side by means of the laser radiation.

In this advantageous development, the solar cells A and B in method step B are arranged in such a way that the back side of one solar cell faces the front side of the other solar cell.

In order to form the arrangement of the solar cells situated next to one another, after the cell connector has been arranged, in one advantageous configuration, the solar cell A or the solar cell B can be flipped over by 180° in a simple manner.

Advantageously, the cell connector is arranged mechanically and electrically non-conductively at an edge side of the solar cell A, and or, preferably and, the cell connector is arranged mechanically and electrically non-conductively at an edge side of the solar cell B. An increased mechanical stability is obtained as a result.

Arranging the cell connector at an edge side of the electrode A and the electrode B enables a particularly efficient method for interconnecting a plurality of solar cells:

In one advantageous development, a plurality of solar cells, preferably at least 3, more particularly preferably 6, more preferably at least 10, solar cells, are arranged next to one another in such a way that in each case at the front side of one solar cell there is arranged the front side of the adjacent solar cell and at the back side of one solar cell there is arranged the back side of the adjacent solar cell. A stack of solar cells is thus formed. At two opposite edge sides of the solar cell stack there is arranged in each case at least one cell connector which covers the edge sides of a plurality of the solar cells of the cell stack, preferably of at least 2, more preferably at least 4, more preferably at least 6, solar cells.

As described above, the cell connectors are electrically conductively connected to the edge sides of the electrodes of the solar cells; the electrically conductive connection is preferably carried out by means of laser radiation.

In this case, the electrically conductive connection is preferably carried out in such a way that a series circuit is made, i.e. an electrode of one contacting type (p-type or n-type) is electrically conductively connected to an electrode of the opposite contacting type of the adjacent solar cell by the cell connector.

In a further method step, the cell connector is separated so that the remaining cell connector segments in each case electrically conductively connect two adjacent solar cells to one another.

Preferably, by swinging out the solar cells, for example rotating each solar cell by 90° alternately in the opposite direction or rotating every second solar cell by 180°, the planar solar cell string is formed.

In one advantageous development, the method is configured for producing a solar cell string in a shingle arrangement:

It is therefore advantageous that in a method step C after method step B, the solar cells are arranged in an overlapping fashion, such that a back-side overlap region of the back side of the solar cell A is arranged over a front-side overlap region of the front side of the solar cell B.

Advantageously, method step B has the following sub-steps:
a. Advantageously, in method step B, in a method step B1, the solar cells A and B are arranged with front sides facing one another or with back sides facing one another, and, in a method step B2, the cell connector is arranged at the solar cell A and at the solar cell B.

This results in simple handling of the cell connector since the latter need not have any folding during the fitting of the cell connector.

In particular, it is advantageous that the electrodes A and B are arranged at the same side of the cell connector.

In order to form the shingle arrangement, the solar cell A or the solar cell B can subsequently be flipped over by 180° in a simple manner.

Advantageously, at least the solar cell B, preferably also the solar cell A, in method step A, is made available as a multi-junction cell for singulation into a plurality of subcells.

It is known to use so-called subcells for forming a solar cell string. Subcells are usually obtained by separating a solar cell into a plurality of subcells. Subcells typically have a rectangular shape in which the length is a multiple of the width.

The method according to the invention makes it possible for the multi-junction cell to be separated and thus the subcell to be separated only after the solar cells have been connected to the cell connector.

It is therefore advantageous that at least the solar cell B, preferably also the solar cell A, in method step A, is made available as a multi-junction cell for singulation into a plurality of subcells, and the multi-junction solar cell is singulated in order to provide the solar cell, in particular by means of laser radiation, the singulation being carried out after method step B, in particular after method step C.

The method according to the invention has the advantage, in particular, that essential method steps can be carried out by means of laser radiation. Advantageously, therefore, the connection of the cell connector to the solar cell A, the connection of the cell connector to the solar cell B, and also the singulation of the multi-junction solar cell in order to provide at least the solar cell B are carried out by means of laser.

The connection of the cell connector to the solar cells is preferably made by means of the method known as Laser Metal Bonding (LMB), as described in Oliver John et al., “Laser Metal Bonding (LMB)—low impact joining of thin aluminum foil to silicon and silicon nitride surfaces”, Procedia CIRP 94 (2020) 863-868, 11th CIRP Conference on Photonic Technologies [LANE 2020] on Sep. 7-10, 2020. In particular, the mechanical, electrically nonconductive connection of cell connector and solar cell is preferably achieved by means of the LMB method described.

### BRIEF DESCRIPTION OF THE DRAWINGS

Further advantageous features and configurations will be explained below on the basis of exemplary embodiments and with reference to the figures. In the figures:

FIG. 1 shows a front and back view of a solar cell A and a solar cell B of one exemplary embodiment of a solar cell string according to the invention;

FIG. 2 shows two different exemplary embodiments of solar cell strings according to the invention;

FIG. 3 shows a front and back view of a multi-junction solar cell for the exemplary embodiment of a method according to the invention which is illustrated in FIG. 4;

FIG. 5 shows a further exemplary embodiment with a Z-shaped cell connector;

FIG. 6 shows a further exemplary embodiment with the cell connector being arranged at edge sides of the solar cells;

FIG. 7 shows a development of the exemplary embodiment shown in FIG. 6, and

FIG. 8 shows a further exemplary embodiment with back-side interconnection.

All of the figures show schematic illustrations which are not true to scale. Identical reference signs in the figures designate identical or identically acting elements.

### DETAILED DESCRIPTION OF THE PREFERRED EMBODIMENTS

FIG. 2 illustrates two exemplary embodiments of a solar cell string according to the invention comprising three solar cells in each case. All the solar cells are configured identically.

In the exemplary embodiments below, the solar cell A described above is configured as a first solar cell 1 and the solar cell B described above is configured as a second solar cell 2. Furthermore, in the examples below, the electrode A is configured as a back-side contacting structure 1b of the first solar cell 1 and the electrode B is configured as a front-side metallization structure 2a of the second solar cell 2.

The first exemplary embodiment of a solar cell string according to the invention, as illustrated in FIG. 2a), comprises a first solar cell 1, a second solar cell 2 and a third solar cell 3. The solar cells (1, 2, 3) are arranged in an overlapping fashion, such that a back-side overlap region of the back side of one solar cell is in each case arranged over a front-side overlap region of the front side of an adjacent solar cell.

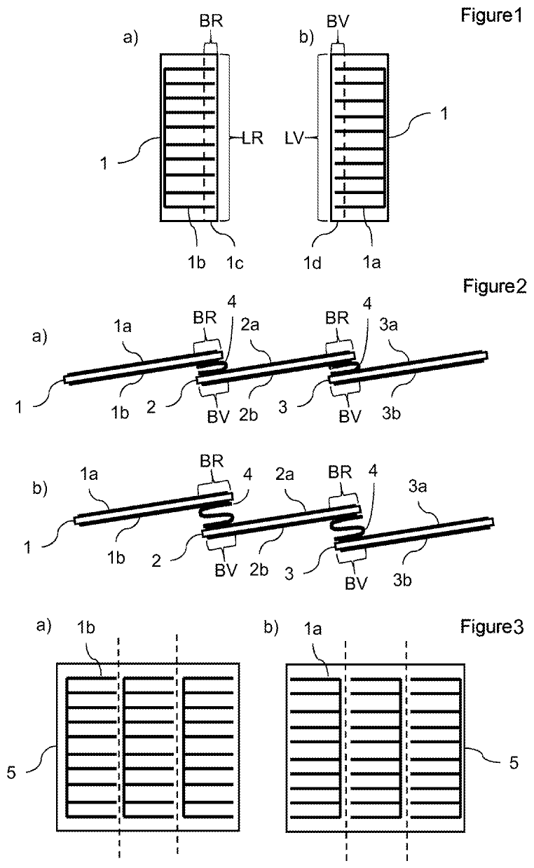

FIG. 1 illustrates a schematic illustration of a plan view of the front side (subfigure a) and a plan view of the back side (subfigure b) of the first solar cell 1. The solar cell is configured as a photovoltaic solar cell based on a silicon substrate, in a manner known per se, and has a metallic front-side contacting structure 1a at the front side and a metallic back-side contacting structure 1b at the back side. Both contacting structures are configured in a comb-like fashion, with rectilinear fingers running parallel to one another. In the schematic illustration in accordance with FIG. 1, each contacting structure 10 has fingers running horizontally.

In the back-side view in accordance with FIG. 1a), a dashed line identifies the back-side overlap region of the back side of the first solar cell 1 with a width BR and a length LR. Accordingly, in the front-side view in accordance with FIG. 1b), a dashed line identifies the front-side overlap region of the front side of the first solar cell with a width BV and a length LV.

As is evident in FIG. 2, the back-side overlap region with a width BR of the first solar cell 1 is arranged over a front-side overlap region with the width BV of the second solar cell 2.

The back side of the first solar cell 1 is electrically conductively connected to the front side of the second solar cell 2.

What is essential is that the back side of the first solar cell 1 is electrically conductively connected to the front side of the second solar cell 2 by means of a flexurally slack cell connector 4. In the present case, the flexurally slack cell connector 4 is configured as an aluminum foil having a thickness of 10 μm. The aluminum foil is a monolayer and uncoated.

As is evident in FIG. 1a), the first solar cell 1 has at the back side the metallic back-side contacting structure 1b, which is configured to conduct electrical charge carriers at the back side of the first solar cell 1 to the back-side overlap region with width BR and length LR or to conduct them away from the latter.

The second solar cell 2 (and also the third solar cell 3) are configured identically to the first solar cell 1. The second solar cell 2 thus has at the front side a front-side contacting structure 2a, which is configured and arranged identically to the front-side contacting structure 1a of the first solar cell 1 shown in FIG. 1b).

The front-side contacting structure of the second solar cell is configured to conduct electrical charge carriers at the front side of the second solar cell to the front-side overlap region (see FIG. 1b) with width BV and length LV or to conduct them away from the latter.

The cell connector 4 is arranged electrically conductively at the back-side contacting structure 1b of the first solar cell 1 in the back-side overlap region with width BV of the first solar cell 1, and is arranged electrically conductively at the front-side contacting structure 2a of the second solar cell 2 in the front-side overlap region (with width BV) of the second solar cell 2.

The cell connector 4 completely covers the back side of the solar cell 1 in the back-side overlap region of the first solar cell 1. In this exemplary embodiment, a cell connector back-side covering region is thus identical to the back-side overlap region of the first solar cell with width BR and length LR.

The width BR of the cell connector back-side metallization covering region is less than 200 μm, in the present case 150 μm.

The cell connector 4 correspondingly covers the front side of the second solar cell in the entire front-side overlap region of the second solar cell 2 with width BV and length LV. Here, too, the cell connector front-side metallization covering region is identical to the front-side overlap region of the second solar cell (with width BV and length LV). The width BV of the cell connector front-side metallization covering region of the second solar cell is likewise 150 μm.

In the present case, the solar cells (1, 2, 3) have a width of 25 mm and a length of 200 mm. Consequently, the width of the cell connector covering regions is only a small proportion of the total width of the solar cell.

The cell connectors 4 each extend over the entire length of the solar cells. The cell connector back-side metallization covering region of the first solar cell 1 thus has a length LR corresponding to the side length of the first solar cell 1 at the back-side overlap region. Likewise, the cell connector front-side metallization covering region of the second solar cell has the length LV corresponding to the side length of the second solar cell at the front-side overlap region.

As is evident in FIG. 2, the back-side overlap region of the first solar cell 1 and the front-side overlap region of the second solar cell 2 are arranged at a common side of the cell connector 4. In the case of the exemplary embodiment illustrated in FIG. 2a), the cell connector 4 has only one fold, in the present case each arranged on the right-hand side in the illustration in accordance with FIG. 2.

As is evident in FIG. 1, both the front-side contacting structure and the back-side contacting structure of the solar cell have a plurality of rectilinear metallic fingers running horizontally in the illustration in accordance with FIG. 1, in each case ten fingers per contacting structure in the schematic illustration in accordance with FIG. 1.

As is furthermore evident in FIG. 1, the fingers of the back-side contacting structure 1b of the first solar cell in the cell connector back-side metallization covering region, which is identical to the back-side overlap region 1c, have no direct connection via the back-side contacting structure 1b. This means that upon separation of the cell connector back-side metallization covering region, there would be no metallic connection between the contacting fingers in the cell connector back-side metallization covering region. As is evident in FIG. 1, the contacting fingers, at the end which does not lie in the cell connector back-side metallization covering region, are electrically conductively connected to one another via a metallic cross-connector, such that upon separation as described above or upon an interruption of a contacting finger, there is nevertheless an electrically conductive connection via the cross-connector.

The cell connector 4 is electrically conductively connected to all the fingers of the back-side contacting structure 1b of the first solar cell. It thus replaces the function of a busbar in previously known contacting structures.

Likewise, the fingers of the front-side contacting structure 2a of the second solar cell 2 in the cell connector front-side metallization covering region, which is identical to the front-side overlap region, have no direct connection via the back-side contacting structure. Here, too, the cell connector 4 is electrically conductively connected to each finger of the front-side contacting structure 2a of the second solar cell 2 in the cell connector front-side metallization covering region.

As is evident in FIG. 1a), the back-side contacting structure 1b of the first solar cell 1 has a metallic cross-connector on the left-hand side in the view in accordance with FIG. 1, which cross-connector electrically conductively connects all ten fingers of the back-side contacting structure 1b to one another. The fingers extend perpendicular to the metallic cross-connector. Correspondingly, the front-side contacting structure 1a of the first solar cell 1 has a metallic cross-connector at the edge side situated opposite the cell connector front-side metallization covering region, which cross-connector electrically conductively connects all ten fingers to one another.

As is evident in FIG. 1a, the back-side contacting structure 1b of the first solar cell covers only a small area of the solar cell. The solar cells 1, 2, 3 are configured as bifacial solar cells, such that even electromagnetic radiation from the back side of the solar cells can penetrate into the solar cell and be absorbed in the semiconductor layers and be converted into electrical energy.

FIG. 2b shows a second exemplary embodiment of a solar cell string according to the invention. The latter differs from the first exemplary embodiment in accordance with FIG. 2a) in that the solar cells connected to the cell connector 4 are arranged at opposite sides of the cell connector 4. Accordingly, the cell connector 4 has two folds. The further technical features correspond to those described with regard to the first exemplary embodiment in accordance with FIG. 2a).

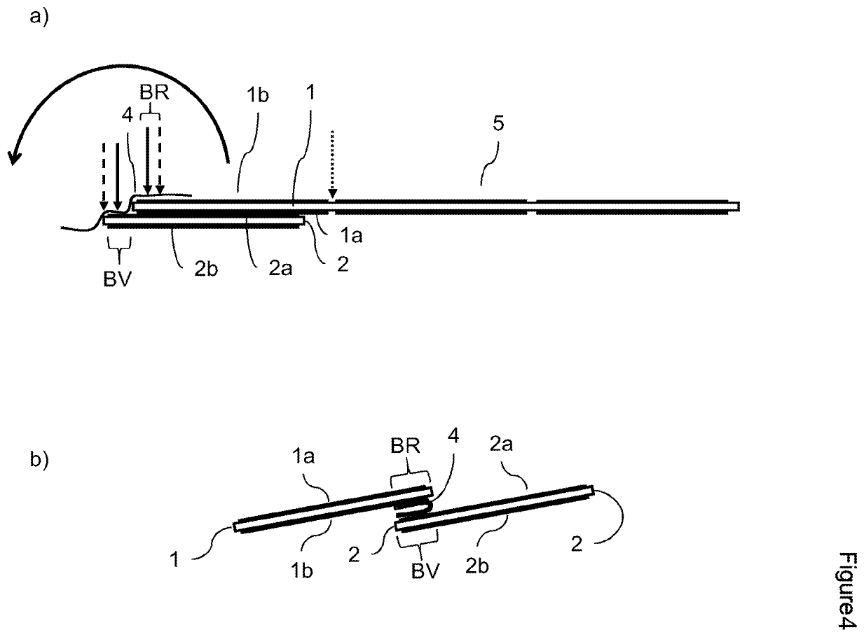

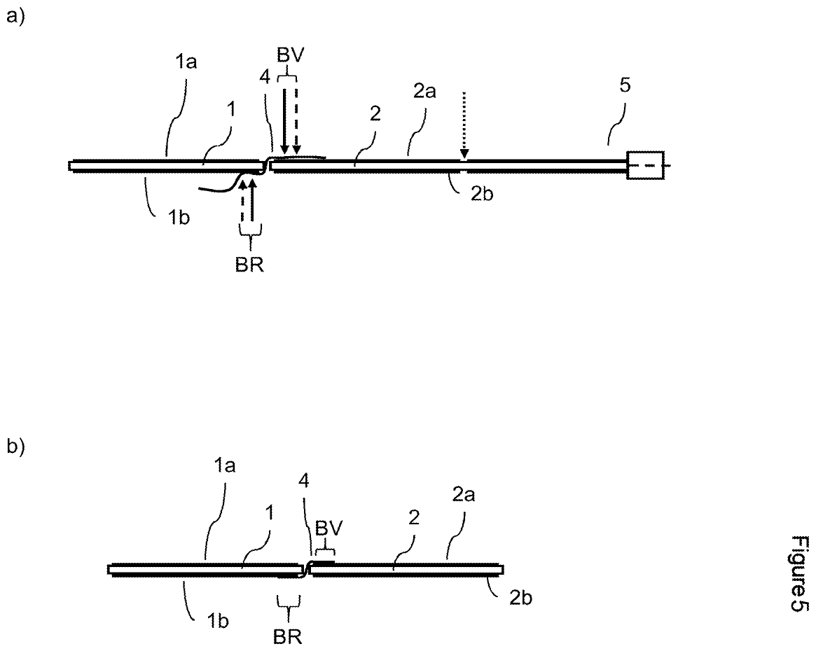

One exemplary embodiment of a method according to the invention is described below with reference to FIGS. 3 and 4. The result of the exemplary embodiment described substantially corresponds to the solar cell string in accordance with FIG. 2a), the fold of the cell connectors 4 being arranged in each case on the left-hand side.

In the exemplary embodiment of the method according to the invention, a method step A involves providing a first and at least one second photovoltaic solar cell. In method step A, the second solar cell is made available as a multi-junction cell for singulation into a plurality of subcells.

FIG. 3 schematically illustrates a back-side view of a multi-junction solar cell 5 in subfigure a and a front-side view of the multi-junction solar cell 5 in subfigure b.

In the present case, the multi-junction solar cell 5 has three sections; the boundaries of these sections are represented by dashed lines in FIG. 5. Each section corresponds, in terms of set-up, to the first solar cell 1 illustrated in FIG. 1. Separation of the multi-junction solar cell 5 at the dashed lines illustrated in FIG. 3 thus yields three partial solar cells, each partial solar cell corresponding to the first solar cell described with regard to FIG. 1.

Accordingly, it is evident in FIG. 3 that at the back side of the multi-junction solar cell 5 there are arranged three back-side contacting structures and at the front side there are arranged correspondingly three front-side contacting structures with in each case ten contacting fingers and a cross-connector.

Method steps of the exemplary embodiment of the method according to the invention are summarized schematically in FIG. 4a).

Firstly, a first and a second photovoltaic solar cell are provided in a method step A.

In this case, provision is made of a second solar cell 2 with the front side at the top and the multi-junction solar cell 5 for providing a first solar cell 1 is arranged with the front side at the bottom on the second solar cell 2, such that the front sides of the two solar cells face one another. In order to form an electrically conductive connection between the back side of the first solar cell 1 and the front side of the second solar cell 2 in a method step B, the arrangement of first solar cell (in the present case in the form of the multi-junction solar cell 5) and second solar cell 2 with front sides facing one another is thus carried out in a sub-step B1, the arrangement being effected in such a way that the front-side overlap region of the second solar cell 2 (with the width BV) is not covered by the first solar cell 1 (and thus not covered by the multi-junction solar cell 5).

In a sub-step B2, a cell connector 4 is arranged at the back-side overlap region of the first solar cell 1 with the width BR and the front-side overlap region of the second solar cell. As is evident in FIG. 4a), in this case the back-side overlap region of the first solar cell 1 and the front-side overlap region of the second solar cell 2 are arranged at the same side of the cell connector 4.

Afterward, the cell connector 4, which in this exemplary embodiment is likewise configured as an aluminum foil as described above, is electrically conductively connected to each finger of the back-side contacting structure 1b of the first solar cell 1 and to each finger of the front-side contacting structure 2a of the second solar cell 2 by means of a laser, by way of the partial melting of the cell connector 4. The laser beams are illustrated schematically as solid arrows.

Afterward, likewise by means of laser beams, excess aluminum foil of the cell connector 4 is separated, if excess material is present. If the cell connector is provided in an accurately fitting manner, separation is not necessary. The laser beams are illustrated schematically as dashed arrows. The separation gives rise to the cell connector overlap region, which in the present case, too, corresponds firstly to the front-side overlap region of the second solar cell 2 and secondly to the back-side overlap region of the first solar cell 1.

Furthermore, the multi-junction solar cell 5 is severed by means of laser radiation in order to separate the first solar cell 1 from the multi-junction solar cell 5. The laser beam is illustrated schematically as a dotted arrow.

The first solar cell 1 is flipped over by 180° in accordance with the curved arrow, thus resulting in the configuration illustrated in FIG. 4b).

In FIG. 5, a further exemplary embodiment of the method according to the invention is illustrated with a sub-step in FIG. 5a) and the resulting exemplary embodiment of a solar cell string according to the invention is illustrated in FIG. 5b).

In this exemplary embodiment, the first solar cell 1 is arranged next to the multi-junction solar cell 5. The cell connector 4 is led in a Z-shape from the back side of the first solar cell 1 to the front side of the second solar cell 2, the cell connector 4 being led between the two solar cells from the back side of the first solar cell to the front side of the second solar cell. As in the exemplary embodiments described above, an electrically conductive connection between the cell connector 4 and firstly the back-side contacting structure 1b of the first solar cell 1 and secondly the front-side contacting structure 2a of the second solar cell 2 is produced in each case by means of laser radiation (solid arrow lines). Excess material of the cell connector 4 is likewise separated by means of laser radiation (arrows with a dashed line).

Afterward, the multi-junction solar cell 6 is severed by means of laser radiation in order to singulate the second solar cell 2 (arrow with dashed line).

The result is illustrated in FIG. 5b.

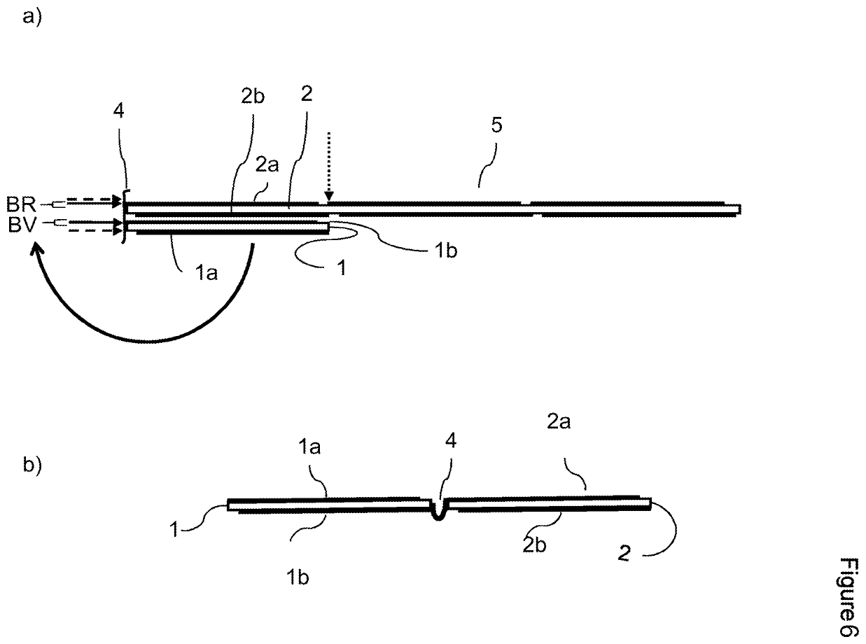

In FIG. 6, a further exemplary embodiment of the method according to the invention is illustrated with a sub-step in FIG. 6a) and the resulting exemplary embodiment of a solar cell string according to the invention is illustrated in FIG. 6b).

The method has commonalities with the method described with regard to FIG. 4. The essential differences are described below:

The first solar cell 1 and the second solar cell 2 are arranged with back sides facing one another, such that the back-side contacting structure 1b of the first solar cell 1 and the back-side contacting structure 2b of the second solar cell 2 are situated opposite one another. The cell connector is arranged at respective front edges of the first solar cell 1 and the second solar cell 2. By means of a laser beam (arrows with solid line), the cell connector 4 is arranged and electrically conductively connected at the edge of the back-side contacting structure 1b of the first solar cell 1. Likewise, the cell connector 4 is arranged and electrically conductively connected at the edge of the front-side contacting structure 2a of the second solar cell.

The contacting structures of the first solar cell 1 and the second solar cell 2 are therefore configured in such a way that in each case at an edge the front-side contacting structure of the solar cell terminates flush with the edge, whereas the back-side contacting structure of the solar cell is spaced apart at this edge, in the present case with a distance of 500 μm. The converse arrangement is formed at the opposite edge: there the back-side contacting structure terminates flush with the edge of the solar cell, whereas the front-side contacting structure is spaced apart from the edge, in the present case with a distance of 500 μm.

As is evident in subfigure a) of FIG. 6, the metallization covering regions are formed with very small widths in this exemplary embodiment. Since the cell connector covers the metallization in each case only at the edge, the width BR of the cell connector front-side metallization covering region corresponds approximately to the height of the front-side contacting structure 2a of the second solar cell and, correspondingly, the width BV of the cell connector back-side metallization covering region corresponds approximately to the height of the back-side contacting structure 1b of the first solar cell 1.

In one development of the exemplary embodiment described above, the cell connector 4 can additionally be attached to the semiconductor substrate of the first solar cell 1 and to the semiconductor substrate of the second solar cell 2 by means of laser radiation, only a mechanical, but not an electrically conductive connection being formed.

Excess material of the cell connector 4 is separated by means of laser radiation (arrows with dashed lines in FIG. 6a).

As described above, in this exemplary embodiment, too, the multi-junction solar cell 6 is separated by means of laser radiation (arrow with dotted line), such that the second solar cell 2 is singulated.

FIG. 6b) shows the end result when, after the cell connector 4 has been arranged at the first solar cell 1 and the second solar cell 2 and the second solar cell 2 has been singulated, the first solar cell 1 is rotated by 180° in accordance with the semicircular arrow in FIG. 6a). The cell connector of the solar cell string is thus situated with a single fold between the first solar cell 1 and the second solar cell 2.

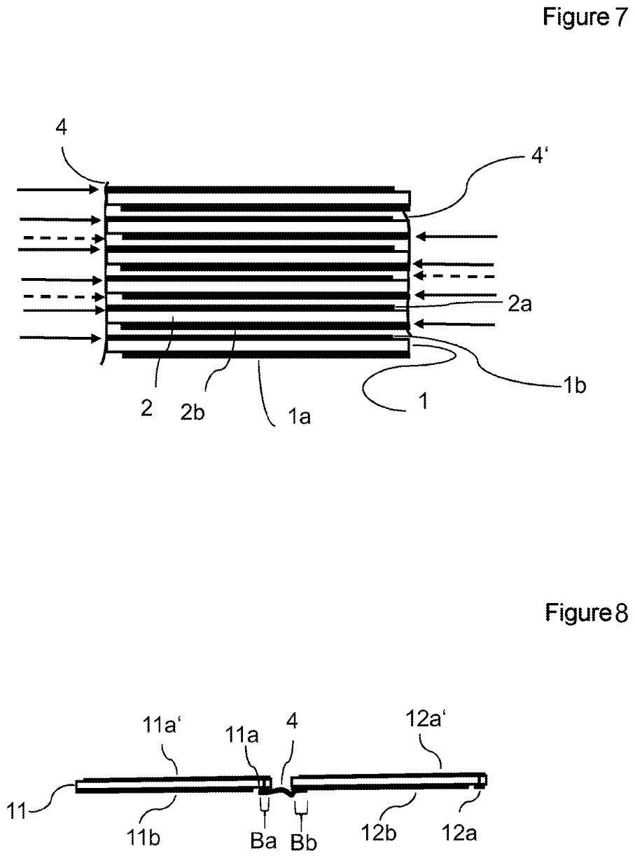

FIG. 7 illustrates a development of the exemplary embodiment shown in FIG. 6:

In order to increase the production efficiency, a stack of solar cells is formed, in each case the front side of one solar cell facing the front side of the adjacent solar cell and the back side of one solar cell facing the back side of the adjacent solar cell. Cell connectors 4, 4′ are arranged at two opposite edge sides of the solar cell stack and are electrically conductively connected at edge sides of the electrodes of the solar cells by means of laser radiation (arrows with solid lines).

By way of example, the bottommost solar cell is identified as the first solar cell 1 (first solar cell A) with front-side contacting structure 1a and back-side contacting structure 1b. The second solar cell B (reference sign 2) is correspondingly arranged in such a way that the back-side contacting structure 2b of the second solar cell 2 faces the back-side contacting structure 1b of the first solar cell 1. This arrangement continues in the stack.

The contacting structures are furthermore configured, as described above, in such a way that a contacting structure terminates flush with the edge of the solar cell at one side, but is spaced apart from the edge of the solar cell at the opposite edge. The contacting structure arranged on the opposite side of the solar cell is arranged in such a way that at each edge only one of the two contacting structures terminates flush with the edge of the solar cell and the other contacting structure is spaced apart from the edge.

As is evident in FIG. 7, the cell connector 4 is electrically conductively connected to the back-side contacting structure 1b of the first solar cell 1 and to the front-side contacting structure 2a of the second solar cell 2 by means of laser radiation. With the solar cells being numbered consecutively proceeding from the first solar cell 1 at the bottom, the cell connector 4 is furthermore electrically conductively connected to the back-side contacting structure of the third and fifth solar cells and to the front-side contacting structure of the fourth and sixth solar cells by means of laser radiation.

At the opposite edge of the solar cell stack, the cell connector 4′ is correspondingly electrically conductively connected to the back-side contacting structure of the second and fourth solar cells and to the front-side contacting structure of the third and fifth solar cells of the solar cell stack.

Afterward, the cell connectors 4, 4′ are separated by means of laser radiation (arrows with dashed lines). The separation is realized in such a way that two solar cells in each case are electrically conductively connected to one another by the resulting segment of the cell connector.

As a result, a series interconnection of the six solar cells illustrated in FIG. 7 is obtained procedurally economically. After the solar cells have been swung out so that all the solar cells lie with the edge sides facing one another in a planar area, a solar cell string comprising six solar cells is formed.

FIG. 8 illustrates a further exemplary embodiment, in which the first solar cell A is configured as an MWT (Metal Wrap Through) solar cell 11 and the second solar cell B is configured as an MWT solar cell 12.

MWT solar cells are distinguished by the fact that they have a front-side contacting structure (front-side contacting structures 11a′ and 12a′ of the solar cells 11 and 12), but the front-side contacting structure is led by way of a metallic connection to the back side, such that a metallic contacting structure for contacting the front-side contacting structure is present on the back side (contacting structures 11a and 12a of the solar cells 11 and 12).

At the back side of the solar cells there is thus arranged firstly a back-side contacting structure (back-side contacting structures 11b and 12b of the solar cells 11 and 12) and also a contacting structure (11a and 12a) that is electrically conductively connected to the front-side contacting structure.

A cell connector 4 connects the contacting structure 11a of the first solar cell 11 to the back-side contacting structure 12b of the second solar cell 12, such that a series interconnection is formed.

### LIST OF REFERENCE SIGNS

1, 11 First solar cell A
1a Front-side contacting structure of the first solar cell A
1b Back-side contacting structure of the first solar cell A
1c Back-side overlap region of the first solar cell A
1d Front-side overlap region of the first solar cell A
2, 12 Second solar cell B
2a Front-side contacting structure of the second solar cell B
2b Back-side contacting structure of the second solar cell B
3 Third solar cell
3a Front-side contacting structure of the third solar cell
3b Back-side contacting structure of the third solar cell
4, 4′ Cell connector
5 Multi-junction solar cell

1. A solar cell string, comprising a first photovoltaic solar cell A (1, 11) and at least one second photovoltaic solar cell B (2, 12), the first photovoltaic solar cell A (1, 11) having at least one first metallic electrode A and the at least one second photovoltaic solar cell B having at least one second metallic electrode B, and the at least one first metallic electrode A being electrically conductively connected to the at least one second metallic electrode B by means of a cell connector (4, 4′) of the solar cell string, wherein the cell connector (4, 4′) is a flexurally slack cell connector (4, 4), which at least partly covers a side of the first photovoltaic solar cell A (1, 11) and the at least one first metallic electrode A in a cell connector covering region A, and the cell connector (4, 4′) is at least partly directly electrically conductively connected to the at least one first metallic electrode A in the cell connector covering region A, and wherein
the cell connector (4, 4′) at least partly covers a side of the at least one second photovoltaic solar cell B (2, 12) and the at least one second metallic electrode B in a cell connector covering region B, and the cell connector (4, 4′) is at least partly directly electrically conductively connected to the at least one second metallic electrode B in the cell connector covering region B,
at least one of the cell connector covering region A or the cell connector covering region B, has a width of less than 1000 μm.

2. The solar cell string as claimed in claim 1, wherein the cell connector covering region A has a length which is greater than 80%, of the side length of the first photovoltaic solar cell A (1, 11) at the cell connector covering region A, and/or, preferably and,
the cell connector covering region B has a length which is greater than 80% of the side length of the at least one second photovoltaic solar cell B (2, 12) at the cell connector covering region B.

3. The solar cell string as claimed in claim 1, wherein the cell connector covering region A is arranged at an edge side of the at least one first metallic electrode A, and or, the cell connector covering region B is arranged at an edge side of the at least one second metallic electrode B.

4. The solar cell string as claimed in claim 1, wherein the cell connector (4, 4′) is arranged mechanically and electrically non-conductively at an edge side of the first photovoltaic solar cell A (1, 11), and or, preferably and,
the cell connector (4, 4′) is arranged mechanically and electrically non-conductively at an edge side of the at least one second photovoltaic solar cell B (2, 12).

5. The solar cell string as claimed in claim 1, wherein the at least one second metallic electrode B has a plurality of rectilinear fingers that run parallel, the fingers not being directly connected by metallic elements of the at least one second metallic electrode B in the cell connector covering region B, and the cell connector (4, 4′) being directly electrically conductively connected to at least 50% of the fingers of the at least one second metallic electrode B, and wherein at least one of:
outside the cell connector covering region B, at the edge side situated opposite the cell connector covering region B, at least two fingers are electrically conductively connected to one another by a metallic cross-connector of the at least one second metallic electrode B, or the at least one first metallic electrode A has a plurality of rectilinear fingers that run parallel, the fingers not being directly connected by metallic elements of the at least one first metallic electrode A in the cell connector covering region A, and the cell connector (4, 4′) being directly electrically conductively connected to at least 50% of the fingers of the at least one first metallic electrode A, or
outside the cell connector covering region A, at the edge side situated opposite the cell connector covering region A, at least two fingers are electrically conductively connected to one another by a metallic cross-connector of the at least one first metallic electrode A.

6. The solar cell string as claimed in claim 1, wherein at least one of:
the at least one first metallic electrode A does not completely cover the cell connector covering region A, and in at least one region not covered by the at least one first metallic electrode A, in a plurality of such regions, the cell connector (4, 4′) is mechanically and electrically non-conductively connected to the first photovoltaic solar cell A, or the at least one second metallic electrode B does not completely cover the cell connector covering region B, and in that in at least one region not covered by the at least one second metallic electrode B, in a plurality of such regions, the cell connector (4, 4′) is mechanically and electrically non-conductively connected to the at least one second photovoltaic solar cell B.

7. The solar cell string as claimed in claim 1, wherein the first photovoltaic solar cell A (1, 11) and at least one second photovoltaic solar cell B (2, 12) are arranged in an overlapping fashion, such that a back-side overlap region of the back side of the first photovoltaic solar cell A is arranged over a front-side overlap region of the front side of the at least one second photovoltaic solar cell B,
the at least one first metallic electrode A is arranged at the back side of the first photovoltaic solar cell A (1, 11) and is configured to conduct electrical charge carriers at the back side of the first photovoltaic solar cell A to the back-side overlap region or to conduct electrical charge carriers away from the the back-side overlap region, and wherein
the at least one second metallic electrode B is arranged at the front side of the at least one second photovoltaic solar cell B (2, 12) and is configured to conduct electrical charge carriers at the front side of the at least one second photovoltaic solar cell B (2, 12) to the front-side overlap region or to conduct electrical charge carriers away from the the front-side overlap region, and wherein,
the cell connector (4, 4′) is arranged electrically conductively at the at least one first metallic electrode A in the back-side overlap region and electrically conductively at the at least one second metallic electrode B in the front-side overlap region.

8. The solar cell string as claimed in claim 7, wherein at least one of: the back-side overlap region and the cell connector covering region A are identical, or, the front-side overlap region and the cell connector covering region B are identical.

9. The solar cell string as claimed in claim 1, wherein the cell connector covering region A and the cell connector covering region B are arranged at a common side of the cell connector.

10. The solar cell string as claimed in claim 1, wherein the first and at least one second photovoltaic solar cells (1, 11, 2, 12) of the solar cell string are configured as bifacial solar cells.

11. The solar cell string as claimed in claim 1, wherein at least one of the cell connector (4, 4′) is configured as a foil and the cell connector (4, 4′) is configured as a monolayer.

12. A solar cell module comprising a plurality of solar cell strings as claimed in claim 1,
wherein the solar cell strings are electrically conductively connected to one another.

13. A method for producing a solar cell string, comprising:
providing a first photovoltaic solar cell A (1,11) and at least one second photovoltaic solar cell B (2,12),
wherein the first photovoltaic solar cell A (1,11) comprises at least one first metallic electrode A (1,11) and the at least one second photovoltaic solar cell B (2,12) comprises at least one second metallic electrode B;
forming an electrically conductive connection between the at least one first metallic electrode A and the at least one second metallic electrode B by means of a cell connector; and wherein the cell connector (4, 4′) is arranged in a manner covering the at least one first metallic electrode A in a cell connector covering region A, and the cell connector (4, 4′) is at least partly directly electrically conductively connected to the electrode A in the cell connector covering region A,
the cell connector (4, 4′) is arranged in a manner covering the electrode B in a cell connector covering region B, and the cell connector (4, 4′) is at least partly directly electrically conductively connected to the at least one second metallic electrode B in the cell connector covering region B,
the cell connector (4, 4′) being arranged at the at least one second metallic electrode B in such a way that the cell connector covering region B in which the cell connector (4, 4′) covers a front side of the at least one second photovoltaic solar cell B has a width of less than 1000 μm,
the connection between the cell connector (4, 4′) and at least the electrode B, between the cell connector (4, 4′) and the at least one first metallic electrode A and the at least one second metallic electrode B, being achieved by way of the action of heat by means of laser radiation.

14. The method for producing a solar cell string as claimed in claim 13, wherein at least one of: the cell connector covering region A is arranged at an edge side of the at least one first metallic electrode A, or
the cell connector covering region B is arranged at an edge side of the at least one second metallic electrode B.

15. The method for producing a solar cell string as claimed in claim 13, wherein at least one of: the cell connector is arranged mechanically and electrically non-conductively at an edge side of the first photovoltaic solar cell A (1, 11), or
the cell connector (4, 4′) is arranged mechanically and electrically non-conductively at an edge side of the at least one second photovoltaic solar cell B (2, 12).

16. The method as claimed in claim 14, wherein the first photovoltaic solar cell A (1,11) and at least one second photovoltaic cell B (2,12) in forming an electrically conductive connection therebetween are arranged in such a way that the back side of one solar cell faces the front side of the other solar cell.

17. The method for producing a solar cell string as claimed in claim 13, further comprising after forming an electrically conductive connection between the at least one first metallic electrode A and the at least one second metallic electrode B, arranging the solar cells in an overlapping fashion, such that a back-side overlap region of the back side of the first photovoltaic solar cell A (1, 11) is arranged over a front-side overlap region of the front side of the at least one second photovoltaic solar cell B (2, 12).

18. The method as claimed in claim 17, wherein in forming an electrically conductive connection between the at least one first metallic electrode A and the at least one second metallic electrode B, the method further comprises arranging the first photovoltaic solar cell A (1, 11) and at least one second photovoltaic solar cell B with front sides facing one another or with back sides facing one another, and
and wherein in forming an electrically conductive connection between the at least one first metallic electrode A and the at least one second metallic electrode B, the cell connector (4, 4′) is arranged at the first photovoltaic solar cell A (1, 11) and at the at least one second photovoltaic solar cell B.

19. The method as claimed in claim 13, wherein forming an electrically conductive connection between the at least one first metallic electrode A and the at least one second metallic electrode B, the method further comprises removing excess cell connector material by separation by means of laser radiation.

20. The method as claimed in claim 13, wherein at least the at least one second photovoltaic solar cell B (2, 12), and the first photovoltaic solar cell A (1, 11), is made available as a multi-junction solar cell (5) for singulation into a plurality of subcells, and the multi-junction solar cell (5) is singulated in order to provide the solar cell, in particular by means of laser radiation,
the singulation being carried out after forming an electrically conductive connection between the at least one first metallic electrode A and the at least one second metallic electrode B.
